(19) United States
(12) Patent Application Publication
(10) Pub. No.: US 2026/0304996 A1
(43) Pub. Date: Oct. 1, 2026

(54) OPTOELECTRONIC SEMICONDUCTOR MODULE

(71) Applicant: AMS-OSRAM International GmbH, Regensburg (DE)

(72) Inventors: Amirhossein GHODS, Longmont, CO (US); David SANDQUIST, St. Paul, MN (US); Jyothy CHEMMACHERILJOBY, Burnsville, MN (US); Klein JOHNSON, Orono, MN (US)

(21) Appl. No.: 19/476,767

(22) PCT Filed: Apr. 12, 2024
(86) PCT No.: PCT/EP2024/059943

§ 371 Date: Oct. 20, 2025

Related U.S. Application Data
(60) Provisional application No. 63/498,532, filed on Apr. 27, 2023.

(51) Int. Cl. H10F 55/25; H10F 10/144; H10F 77/40

(52) U.S. Cl. CPC H10F 55/25; H10F 10/144; H10F 77/407

(57) ABSTRACT

An optoelectronic semiconductor module includes a light source having at least one semiconductor emitter and a photovoltaic module having at least one photovoltaic element arranged on a substrate. The light source is configured to emit a first electromagnetic radiation. The photovoltaic module is configured to convert at least part of the optical power of the first electromagnetic radiation into an electric power. The photovoltaic module includes an absorbing buffer layer.

The present application relates to an optoelectronic semiconductor module. In particular, the optoelectronic module is configured to convert an electric input power signal to an output power signal having a different voltage and/or current.

It is an object of the present disclosure to provide an optoelectronic semiconductor module having improved reliability.

This object is achieved by a device according to the independent patent claim. Advantageous embodiments and further developments of the device are the subject of the dependent patent claims and are furthermore apparent from the following description and the figures.

According to at least one embodiment the optoelectronic semiconductor module comprises a light source having at least one semiconductor emitter. Preferably, the semiconductor module comprises a base body on which the semiconductor emitter is arranged. In particular, the base body is formed to be mechanically self-supporting. For example, the semiconductor emitter is arranged on a side of the base body facing the photovoltaic module. Alternatively, the semiconductor emitter is arranged on a side of the base body facing away from the photovoltaic module. Preferably, the base body is formed with a material that is translucent for the electromagnetic radiation generated in the emitter during intended operation.

The semiconductor emitter is configured, for example, to emit an electromagnetic radiation in a main emission direction during intended operation. The main emission direction is preferably oriented perpendicular to a main plane of extension of the base body of the light source.

According to at least one embodiment the optoelectronic semiconductor module comprises a photovoltaic module having at least one photovoltaic element arranged on a substrate. The photovoltaic module is particularly suitable for converting optical power into electrical power. The substrate is preferably mechanically self-supporting. In particular, the substrate is a growth substrate for the photovoltaic elements. For example, the substrate is formed with a semi-insulating material, in particular with GaAs. Furthermore, the main emission direction of the light source is in particular oriented towards the photovoltaic module.

According to at least one embodiment of the optoelectronic semiconductor module, the light source is configured to emit a first electromagnetic radiation. In particular, the first electromagnetic radiation has a main wavelength in a spectral region starting with the spectrum visible to the human eye, i.e. between 380 nm and 780 nm, and extending to the infrared spectral region between 780 nm and 2 μm. For example, a main wavelength of the light source is between 800 nm and 900 nm. A main wavelength is to be understood as a wavelength in an emission spectrum where the intensity reaches a global maximum.

According to at least one embodiment of the optoelectronic semiconductor module, the photovoltaic module is configured to convert at least part of the optical power of the first electromagnetic radiation into an electric power. In particular, the first electromagnetic radiation has a main wavelength overlapping with an absorption spectrum of the photovoltaic module. Preferably, the absorption spectrum of the photovoltaic module comprises a peak in the region of the main emission wavelength of the light source.

According to at least one embodiment of the optoelectronic semiconductor module, the photovoltaic module comprises an absorbing buffer layer. The absorbing buffer layer is configured to absorb the first electromagnetic radiation. For example, the absorbing buffer layer absorbs at least 90% of the incident first electromagnetic radiation which propagates through the absorbing buffer layer. Preferably, the absorbing buffer layer absorbs at least 99% of the incident first electromagnetic radiation which propagates through the absorbing buffer layer, and particularly preferably the absorbing buffer layer absorbs at least 99.9% of the incident first electromagnetic radiation which propagates through the absorbing buffer layer. Preferably the absorbing buffer layer is configured to absorb the first electromagnetic radiation which is incident on the regions of the photovoltaic module, where the substrate would otherwise be directly exposed to the incident first electromagnetic radiation.

The absorbing buffer layer is preferably arranged on a side of the substrate facing the light source between the photovoltaic elements. In particular, the absorbing buffer layer is at least covering lateral portions between adjacent photovoltaic elements.

According to at least one embodiment the optoelectronic semiconductor module comprises:
a light source having at least one semiconductor emitter, and
a photovoltaic module having at least one photovoltaic element arranged on a substrate, wherein
the light source is configured to emit a first electromagnetic radiation,
the photovoltaic module is configured to convert at least part of the optical power of the first electromagnetic radiation into an electric power, and
the photovoltaic module comprises an absorbing buffer layer.

An optoelectronic semiconductor module described herein is based, inter alia, on the following considerations:

Optoelectronic modules for a wireless optical power transmission system often include a light source (e.g. VCSEL, edge-emitting laser, LED, etc.) in front of a light absorbing device (e.g. photovoltaic module).

The output power from the light source is optically transmitted to the photovoltaic module, where it is converted back to electrical power. The objective of this process, in addition to eliminating the need for wires as a physical medium to transfer the electrical power, can be to step up/down the voltage or current at the output terminals of the photovoltaic module compared to the input terminals of the light source. Therefore, the photovoltaic elements can be connected to each other in the form of arrays, where the photovoltaic elements are connected in series or parallel to each other depending on whether current or voltage are to be boosted or lowered.

In known transmission systems one light source aperture exists for each photovoltaic element aperture. However, the placement of emitters and photovoltaic elements in front of each other with perfect positional alignment can be difficult. A small offset either laterally and/or rotationally can change the position of the light beam incident on the one photovoltaic module. A misalignment between the light source and the photovoltaic module can result in that at least part of the light beam emitted by the light source is not fully incident within the photovoltaic module. In other words, the misalignment can lead to non-active regions of the photovoltaic module, which impairs reliability and efficiency of the optoelectronic module.

Moreover, a further challenge created by this situation is a substrate leakage that is formed in the photovoltaic module. Typically, the photovoltaic module is directly grown/placed on a semi-insulating, highly resistive GaAs substrate. In case the material of the substrate is directly exposed to light (which could for example be caused by a positional misalignment between the light source and the photovoltaic module), its resistivity drops significantly and it thus becomes conductive. This can create a current leakage path underneath the photovoltaic element that can short it entirely.

The optoelectronic semiconductor module described herein is based, among other things, on the idea of arranging an absorbing buffer layer between the substrate and the photovoltaic elements. This absorbing buffer layer can be closely lattice-matched to the underlying semi-insulating gallium arsenide (GaAs) substrate. For example, the absorbing buffer layer has a smaller bandgap Eg than the photon energy of the incoming first electromagnetic radiation. Additionally, the absorbing buffer layer can be made thick enough to absorb most of the first electromagnetic radiation that propagates through the absorbing buffer layer. Furthermore, the absorbing buffer layer can have a relatively high electrical resistivity, so that it can provide electrical isolation between neighboring photovoltaic elements. The effect of the absorbing buffer layer in preventing an optically induced leakage in the substrate further enables the use of alternative illumination methods and light sources.

According to at least one embodiment the optoelectronic semiconductor module comprises a light diffuser element arranged between the light source and the photovoltaic module. Preferably, the light diffuser element blocks every direct connection of a light ray propagating between the light source and the photovoltaic module. By means of the light diffuser element, a rotational and/or lateral misalignment of the light source relative to the photovoltaic module is tolerable because the diffuser element converts the single light emission beam of the emitter into a homogenous illumination of the whole photovoltaic module.

According to at least one embodiment of the optoelectronic semiconductor module, the diffuser element is configured to diffuse the first electromagnetic radiation. The light diffuser element in particular scatters light in some manner to transmit soft light. The light diffuser element is for example a refractive element or a diffractive element for the first electromagnetic radiation. The light diffuser element is in particular permeable for the first electromagnetic radiation. The diffused light illuminates the photovoltaic module homogenously and advantageously eases the requirements for the alignment of the light source relative to the photovoltaic module.

According to at least one embodiment of the optoelectronic semiconductor module, the semiconductor emitter is a VCSEL. A vertical-cavity surface-emitting laser, VCSEL for short, is a laser diode in which the light is emitted perpendicular to a main plane of extension of the semiconductor emitter. Advantageously, VCSEL diodes can have low manufacturing costs compared to edge emitters and a better beam quality. Furthermore, VCSELs can emit a coherent radiation in monomode and the wavelength can be easily determined by the structure.

According to at least one embodiment of the optoelectronic semiconductor module, the semiconductor emitter is a light emitting diode, preferably a micro-LED.

A light emitting diode preferably emits an electromagnetic radiation with a broader spectral range compared to a VCSEL diode. Advantageously, a light emitting diode can emit electromagnetic radiation in a wide angle and thus enables a homogenous illumination of a large area. Light emitting diodes are also available in particularly small sizes in the form of micro-LEDS.

As a broad definition, a micro-LED could be seen as any light emitting diode (LED)—generally not a laser—with a particularly small size. As a rule—and this is a very important criterion in addition to size—a growth substrate is removed from micro-LEDs, so that typical heights of such micro-LEDs are in the range of 1.5 μm to 10 μm, for example.

In principle, a micro-LED does not necessarily have to have a rectangular radiation emission surface. Generally, for example, an LED could have a radiation emission surface in which, in top view of the layers of the layer stack, any lateral extent of the radiation emission surface is less than or equal to 100 μm or less than or equal to 70 μm.

For example, in the case of rectangular micro-LEDs, an edge length—especially in top view of the layers of the layer stack—less than or equal to 70 μm or less than or equal to 50 μm is often cited as a criterion. Mostly, such micro-LEDs are provided on wafers with—for the micro-LED non-destructively—detachable holding structures. At present, micro-LEDs are mainly used in displays.

The micro-LEDs form pixels or subpixels and emit light of a defined color. Small pixel size and a high density with close distances make micro-LEDs suitable, among others, for small monolithic displays for AR applications, especially data glasses. In addition, other applications are being developed, in particular regarding the use in data communication or pixelated lighting applications.

Different ways of spelling micro-LED, e.g. μLED, μ-LED, uLED, u-LED or micro light emitting diode, can be found in the relevant literature.

According to at least one embodiment of the optoelectronic semiconductor module, the light source comprises only one semiconductor emitter. The use of one emitter simplifies the manufacturing of the semiconductor module and can further save costs.

According to at least one embodiment of the optoelectronic semiconductor module, the light source comprises a plurality of semiconductor emitters. By arranging a plurality of semiconductor emitters in the light source, a preferably homogenous light emission can be achieved.

According to at least one embodiment of the optoelectronic semiconductor module, the photovoltaic module comprises a plurality of photovoltaic elements. For example, the photovoltaic elements are arranged in an array. The photovoltaic elements can electrically be connected in series or parallel, in order to produce a high current or a high voltage.

According to at least one embodiment of the optoelectronic semiconductor module, each photovoltaic element is assigned to one semiconductor emitter. In other words, there is exactly one photovoltaic element for each semiconductor emitter.

According to at least one embodiment of the optoelectronic semiconductor module, the absorbing buffer layer is formed epitaxially. For example, the absorbing buffer layer is formed by an epitaxial growth process. In particular the absorbing buffer layer is lattice-matched to the material of the substrate.

According to at least one embodiment of the optoelectronic semiconductor module, the absorbing buffer layer is formed with a material having a bandgap Eg which is lower than the energy of the first electromagnetic radiation. The energy of the first electromagnetic radiation is described with the photon energy which is directly proportional to the frequency of the first electromagnetic radiation. In other words, the bandgap E_{g}<h*f, wherein h is the Planck constant and f is the frequency of the first electromagnetic radiation. In particular, the absorbing buffer layer is formed with a semiconductor material.

According to at least one embodiment of the optoelectronic semiconductor module, the absorbing buffer layer is formed with a material having an optical absorption coefficient of at least 5000 cm⁻¹. Such a high optical absorption coefficient enables a high absorption within a small vertical distance. This allows for an advantageously thin absorbing buffer layer.

According to at least one embodiment of the optoelectronic semiconductor module, the absorbing buffer layer is formed with one of the following materials: gallium antimonide, aluminum arsenide, indium gallium arsenide, aluminum gallium arsenide, or combinations thereof. These materials have a high optical absorption coefficient for the first electromagnetic radiation.

According to at least one embodiment of the optoelectronic semiconductor module, a maximal distance between the diffuser element and the light source is at most 300 μm, preferably at most 100 μm, and more preferably at most 20 μm. A short distance between the light source and the diffuser element enables a particularly diffuse light emission.

According to at least one embodiment of the optoelectronic semiconductor module, the diffuser element is attached to the light source. An arrangement of the diffuser element directly at the light source allows for an advantageously small form factor.

According to at least one embodiment of the optoelectronic semiconductor module, the diffuser element comprises at least one micro lens. In particular the diffuser element comprises a plurality of micro lenses. For example the micro lenses are arranged in a defocused manner relative to the light source in order to create a blurred image.

According to at least one embodiment of the optoelectronic semiconductor module, the diffuser element is formed with at least one of the following materials: polymer, glass, metamaterial. In particular, the diffuser element comprises a translucent matrix material in which particles of optically scattering materials are embedded. The scattering material are for example made with titanium dioxide or barium sulfate.

An optoelectronic semiconductor module described herein is particularly suitable for use in optical power transmitters or optical voltage transformers for example to power avalanche photo diodes requiring a high voltage.

Further advantages and advantageous designs and further developments of the optoelectronic semiconductor module will become apparent from the following exemplary embodiments, which are described below in association with the figures.

In the figures:

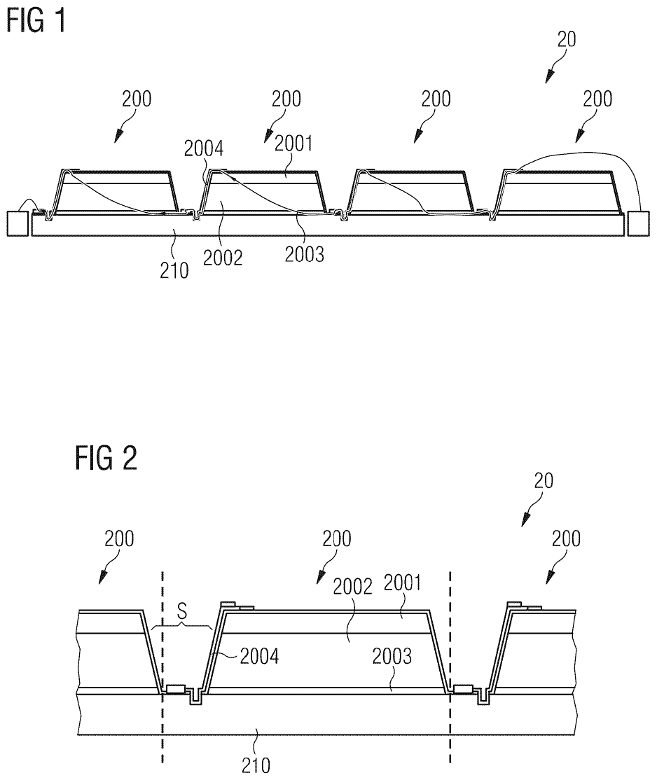

FIG. 1 shows a schematic cross-sectional view of a photovoltaic module described herein according to a first exemplary embodiment,

FIG. 2 shows a detailed view of the schematic cross-sectional view of a photovoltaic module described herein according to the first exemplary embodiment,

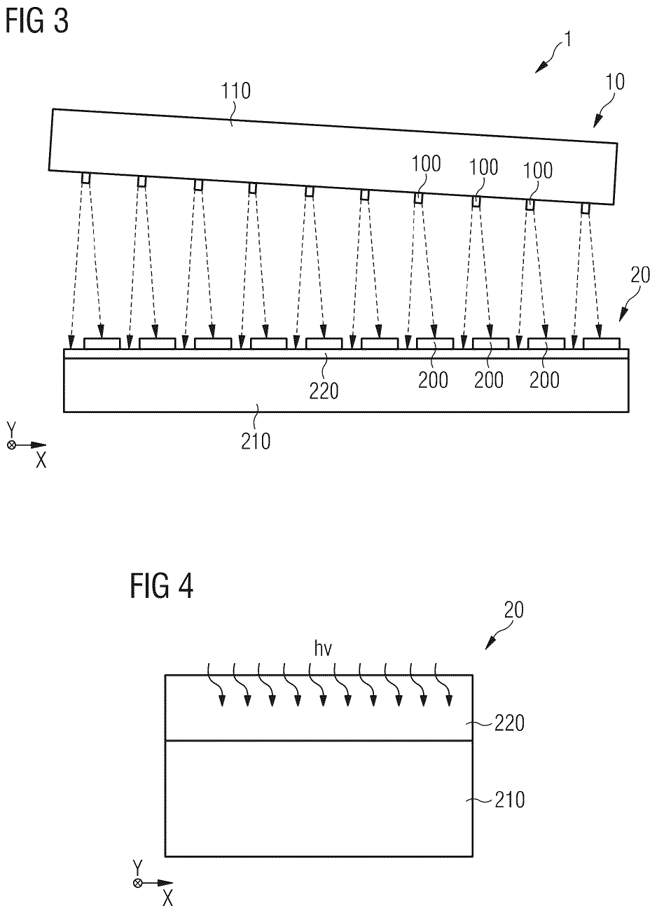

FIG. 3 shows a schematic cross-sectional view of an optoelectronic semiconductor module described herein according to a first exemplary embodiment,

FIG. 4 shows a schematic cross-sectional view of a substrate of a photovoltaic module described herein according to a second exemplary embodiment,

FIG. 5 shows a graph of an optical transmittance in an absorbing buffer layer of a photovoltaic module described herein according to the second exemplary embodiment,

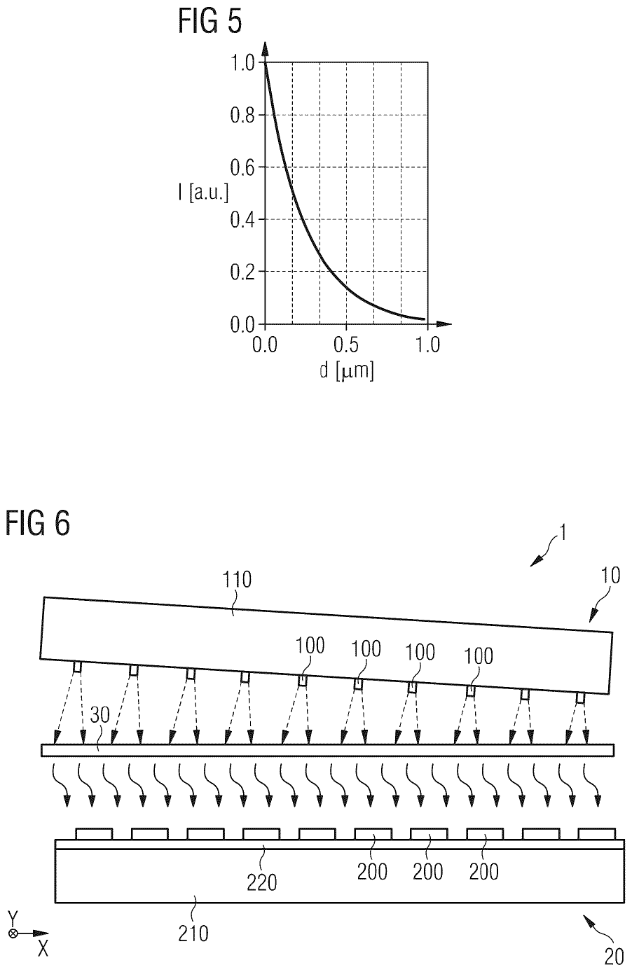

FIG. 6 shows a schematic cross-sectional view of an optoelectronic semiconductor module described herein according to a second exemplary embodiment,

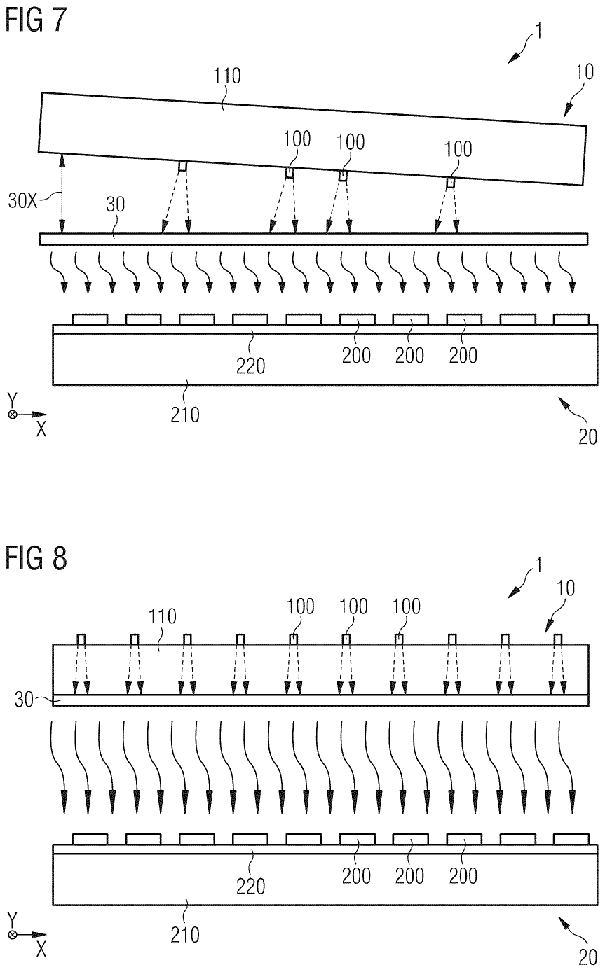

FIG. 7 shows a schematic cross-sectional view of an optoelectronic semiconductor module described herein according to a third exemplary embodiment, and

FIG. 8 shows a schematic cross-sectional view of an optoelectronic semiconductor module described herein according to a fourth exemplary embodiment.

Identical, similar or equivalent elements are marked with the same reference signs in the figures. The figures and the proportions of the elements represented in the figures among each other are not to be considered as true to scale. Rather, individual elements may be oversized for better representability and/or comprehensibility.

FIG. 1 shows a schematic cross-sectional view of a photovoltaic module 20 described herein according to a first exemplary embodiment. The photovoltaic module 20 comprises a plurality of photovoltaic elements 200 arranged on a substrate 210. The photovoltaic module 20 is designed to have a global maximum in its absorption spectrum at 850 nm for example.

Each photovoltaic element 200 comprises a first region 2001, a second region 2002 and a third region 2003 stacked on top of each other. The first region 2001 is an n-conducting semiconductor region. The second region 2002 is a p-conducting semiconductor region. The third region 2003 is an anode region. For example, the photovoltaic module 20 is formed with GaAs. Each photovoltaic element 200 comprises at least one electrically active region, as a single-junction element, located between the first region 2001 and the second region 2002. This active region generates charge carriers if light having a wavelength inside an absorption spectrum of the photovoltaic element 200 is incident. In particular, each photovoltaic element 200 can comprise a plurality of active regions, as a multi-junction element.

Thus, the photovoltaic element 200 generates an electrical voltage during operation and converts an optical power to an electrical power. Moreover, a contact element 2004 is attached to the photovoltaic element 200 and connects an anode region 2003 of an adjacent photovoltaic element 200 with a first region 2001 of the photovoltaic element 200. Thus, the plurality of photovoltaic elements 200 is connected in series. This enables the generation of a high voltage. Alternatively, all photovoltaic elements 200 can be connected parallel to each other in order to create a high current with a lower voltage.

FIG. 2 shows a detailed view of the schematic cross-sectional view of a photovoltaic module 20 described herein according to the first exemplary embodiment. The detailed view in FIG. 2 clearly shows the arrangement of the contact element 2004 between two adjacent photovoltaic elements 200 and the empty space S. If the substrate 210 is illuminated by the first electromagnetic radiation, for example in the empty space S between adjacent photovoltaic elements 200, this can cause an unwanted generation of free charge carriers in the substrate, which can drastically reduce an electrical resistivity of the substrate and thus cause leakage currents and short circuits of the photovoltaic module 20.

FIG. 3 shows a schematic cross-sectional view of an optoelectronic semiconductor module 1 described herein according to a first exemplary embodiment. The optoelectronic semiconductor module 1 comprises a light source 10 having a plurality of semiconductor emitters 100 arranged on a base body 110. The base body 110 is formed with a mechanically stable material, for example a growth substrate formed with sapphire. In particular, a mechanically stable element is a self-supporting body. The semiconductor emitters 100 are arranged on a side of the base body 110 facing the photovoltaic module 20.

Moreover, the semiconductor emitters 100 are configured to emit an electromagnetic radiation in a main emission direction during intended operation. The main emission direction is preferably oriented perpendicular to a main plane of extension of the optoelectronic semiconductor module 1.

The optoelectronic semiconductor module 1 further comprises a photovoltaic module 20 having a plurality of photovoltaic elements 200 arranged on a substrate 210. For each emitter 100 a dedicated photovoltaic element 200 is assigned.

The photovoltaic module 20 is particularly suitable for a conversion of optical power into electrical power. The substrate 210 is preferably mechanically self-supporting. In particular, the substrate 210 is a growth substrate for the photovoltaic elements 200. For example, the substrate 210 is formed with GaAs.

The light source 10 is configured to emit a first electromagnetic radiation. In particular, the first electromagnetic radiation has a main wavelength in a spectral region starting with the spectrum visible to the human eye, i.e. between 380 nm and 780 nm, and extending to the infrared spectral region between 780 nm and 2 μm. A main wavelength is to be understood as a wavelength in an emission spectrum where the intensity reaches a global maximum. For example, a main wavelength of the light source is between 800 nm and 900 nm.

The photovoltaic module 20 is configured to convert at least part of the optical power of the first electromagnetic radiation into an electric power. In particular, the first electromagnetic radiation has a main wavelength overlapping with an absorption spectrum of the photovoltaic module 20. Preferably, the absorption spectrum of the photovoltaic module 20 comprises a peak in the region of the main emission wavelength of the light source 10.

The photovoltaic module 20 further comprises an absorbing buffer layer 220. The absorbing buffer layer 220 is configured to absorb the first electromagnetic radiation. For example, the absorbing buffer layer 220 absorbs at least 90% of the incident first electromagnetic radiation which propagates through the absorbing buffer layer 220. Preferably, the absorbing buffer layer 220 absorbs at least 99% of the incident first electromagnetic radiation which propagates through the absorbing buffer layer 220, and particularly preferably the absorbing buffer layer 220 absorbs at least 99.9% of the incident first electromagnetic radiation which propagates through the absorbing buffer layer 220. The absorbing buffer layer 220 is preferably arranged on a side of the substrate 210 facing the light source 10 between the photovoltaic elements 200. In particular, the absorbing buffer layer 220 is at least covering lateral portions between adjacent photovoltaic elements 200.

In consequence, even a slight lateral and/or rotational and/or non-planar misalignment of the light source 10 relative to the photovoltaic module 20 is tolerable, because the unwanted generation of free charge carriers in the substrate 210 is prevented by the absorbing buffer layer 220.

FIG. 4 shows a schematic cross-sectional view of a substrate 210 of a photovoltaic module 20 described herein according to a second exemplary embodiment. The detailed view of FIG. 4 shows the incident first electromagnetic radiation on the photovoltaic module 20. The photovoltaic module 20 comprises an absorbing buffer layer 220 arranged on the substrate 210 of the photovoltaic module 20. The absorbing buffer layer 220 is arranged on a side of the substrate 210 facing a light source 10 which is emitting a first electromagnetic radiation. The first electromagnetic radiation is preferably at least partially absorbed in the absorbing buffer layer 220 and thus does not reach the substrate 210 with its full intensity. For example, less than 0.1% of the intensity of the first electromagnetic radiation reaches the substrate 210 after propagating through the absorbing buffer layer 220. Preferably, the first electromagnetic radiation is fully absorbed in the absorbing buffer layer 220 and does not reach the substrate 210.

FIG. 5 shows a graph of an optical transmittance in an absorbing buffer layer 220 of a photovoltaic module 20 described herein according to the second exemplary embodiment. The graph shows the optical intensity of the first electromagnetic radiation while propagating through the absorbing buffer layer 220. The intensity drastically decreases with increasing distance d of propagation. After propagating through a distance d of 0.5 μm, only less than 20% of an initial intensity of the first electromagnetic radiation is left.

FIG. 6 shows a schematic cross-sectional view of an optoelectronic semiconductor module 1 described herein according to a second exemplary embodiment. The second exemplary embodiment is essentially equal to the first exemplary embodiment shown in FIG. 3.

Additionally, the optoelectronic semiconductor module 1 comprises a light diffuser element 30 arranged between the light source 10 and the photovoltaic module 20. Preferably, the light diffuser element 30 blocks every direct connection of a light ray propagating between the light source 10 and the photovoltaic module 20.

The diffuser element 30 is configured to diffuse the first electromagnetic radiation. The light diffuser element 30 in particular scatters light in some manner to transmit soft light. The light diffuser element 30 is for example a refractive element, a diffractive element, or a pattern of elements for the first electromagnetic radiation. The light diffuser element 30 is in particular permeable for the first electromagnetic radiation.

The light diffuser element 30 enables a homogenous illumination of the photovoltaic module 20, wherein the absorbing buffer layer 220 prevents an illumination of the substrate 210 in order to avoid leakage currents in the substrate.

FIG. 7 shows a schematic cross-sectional view of an optoelectronic semiconductor module 1 described herein according to a third exemplary embodiment. The third exemplary embodiment is essentially equal to the second exemplary embodiment shown in FIG. 6. However, the number of semiconductor emitters 100 is less than the number of photovoltaic elements 200. Alternatively, the light source 10 could comprise only one semiconductor emitter 100 to illuminate a plurality of photovoltaic elements 200.

Furthermore, a maximal distance 30X between the diffuser element 30 and the light source 10 is at most 300 μm, preferably at most 100 μm, and more preferably at most 20 μm. A short distance 30X between the light source 10 and the diffuser element 30 enables a particularly diffuse light emission. Additionally, having a small distance 30X between the diffuser element 30 and the light source 10 also requires a smaller diffuser element 30, since the light beams of the light source 10 diverge with increasing distance to the light source 10.

FIG. 8 shows a schematic cross-sectional view of an optoelectronic semiconductor module 1 described herein according to a fourth exemplary embodiment. The fourth exemplary embodiment is essentially equal to the second exemplary embodiment shown in FIG. 6. In contrast, the semiconductor emitters 100 are arranged on a side of the base body 110 which is facing away from the photovoltaic module 20. The base body 110 is formed with a material that is translucent for the first electromagnetic radiation.

The light diffuser element 30 is attached to the light source 10. The first electromagnetic radiation propagates through the base body 110 first and through the light diffuser element 30 second before reaching the photovoltaic module 20. Such an optoelectronic semiconductor module 1 can also be called a bottom-emitting device.

The invention described herein is not limited by the description given with reference to the exemplary embodiments. Rather, the invention encompasses any novel feature and any combination of features, including in particular any combination of features in the claims, even if this feature or this combination is not itself explicitly indicated in the claims or exemplary embodiments.

This patent application claims the priority of the U.S. provisional patent application 63/498,532, the disclosure content of which is hereby incorporated by reference.

### REFERENCES

1 optoelectronic semiconductor module
10 light source
100 semiconductor emitter
110 base body
20 photovoltaic module
200 photovoltaic element
2001 first region
2002 second region
2003 third region
2004 contact element
210 substrate
220 absorbing buffer layer
30 light diffuser element
30X distance
S space

1. An optoelectronic semiconductor module, comprising:
a light source having at least one semiconductor emitter, and
a photovoltaic module having at least one photovoltaic element arranged on a substrate, wherein
the light source is configured to emit a first electromagnetic radiation,
the photovoltaic module is configured to convert at least part of the optical power of the first electromagnetic radiation into an electric power, and
the photovoltaic module comprises an absorbing buffer layer.

2. The optoelectronic semiconductor module according to claim 1, further comprising
a light diffuser element is arranged between the light source and the photovoltaic module, wherein
the diffuser element is configured to diffuse the first electromagnetic radiation.

3. The optoelectronic semiconductor module according to claim 1, wherein
the semiconductor emitter is a VCSEL.

4. The optoelectronic semiconductor module according to claim 1, wherein
the semiconductor emitter is a light emitting diode, preferably a micro-LED.

5. The optoelectronic semiconductor module according to claim 1, wherein
the light source comprises only one semiconductor emitter.

6. The optoelectronic semiconductor module according to claim 1, wherein
the light source comprises a plurality of semiconductor emitters.

7. The optoelectronic semiconductor module according to claim 1, wherein
the photovoltaic module comprises a plurality of photovoltaic elements.

8. The optoelectronic semiconductor module according to claim 1, wherein
each photovoltaic element is assigned to one semiconductor emitter.

9. The optoelectronic semiconductor module according to claim 1, wherein
the absorbing buffer layer is formed epitaxially.

10. The optoelectronic semiconductor module according to claim 1, wherein
the absorbing buffer layer is formed with a material having a bandgap Eg which is lower than the energy of the first electromagnetic radiation.

11. The optoelectronic semiconductor module according to claim 1, wherein
the absorbing buffer layer is formed with a material having an optical absorption coefficient of at least 5000 cm⁻¹.

12. The optoelectronic semiconductor module according to claim 1, wherein
the absorbing buffer layer is formed with one of the following materials: gallium antimonide, aluminum arsenide, indium gallium arsenide, aluminum gallium arsenide, or combinations thereof.

13. The optoelectronic semiconductor module according to claim 1, wherein
a maximal distance between the diffuser element and the light source is at most 300 μm, preferably at most 100 μm, and more preferably at most 20 μm.

14. The optoelectronic semiconductor module according to claim 1, wherein
the diffuser element is attached to the light source.

15. The optoelectronic semiconductor module according to claim 1, wherein
the diffuser element comprises at least one micro lens.

16. The optoelectronic semiconductor module according to claim 1, wherein
the diffuser element is formed with at least one of the following materials: polymer, glass, metamaterial.
